(19) United States
(12) Patent Application Publication
(10) Pub. No.: US 2021/0129681 A1
(43) Pub. Date: May 6, 2021

(54) FOLDABLE INFLATABLE CONCENTRATING PHOTOVOLTAIC SYSTEM BASED SOLAR TRAILER POWERED ELECTRIC CAR

(71) Applicant: Yonghua Wang, Klamath Falls, OR (US)

(72) Inventor: Yonghua Wang, Klamath Falls, OR (US)

(21) Appl. No.: 16/602,574

(22) Filed: Nov. 4, 2019

(51) Int. Cl. B60L 8/00; H02S 10/40; H02S 30/20; H02S 40/38; H02S 40/22; H02J 7/35; B60L 53/51

(52) U.S. Cl. CPC B60L 8/003; H02S 10/40; H02S 30/20; B60L 2200/28; H02S 40/22; H02J 7/35; B60L 53/51; H02S 40/38

(57) ABSTRACT

A solar powered electric vehicle comprising a conventional electric vehicle and an inflatable non-imaging solar concentrator based concentrating photovoltaic system trailer. The trailer is super-light and able to charge the front electric vehicle when it is moving. The inflatable non-imaging solar concentrator can concentrate both beam light and diffuse light. The inflatable non-imaging solar concentrator dramatically reduces the area of the semiconductor receiver of the concentrating photovoltaic system and significantly reduces its cost. The trailer is made foldable by hanging multiple trailer units mounted with the inflatable non-imaging solar concentrator based concentrating photovoltaic systems.

### TECHNICAL FIELD

The present disclosure relates generally to solar car, more specifically, to a foldable inflatable concentrating photovoltaic system based solar trailer powered electric car.

### BACKGROUND

Solar car has been always fascinating to younger generations. The solar car race event in Australia attracted many teams from universities over the world each time. However, contrast to the power needed to power a real car, the power generated from the limited surface area of a conventional car is far away from enough to power the conventional car. The state of the art of the current photovoltaic technology has only reached the record conversion efficiency 46.5% and the conventional silicon solar cells have only approached to the record conversion efficiency of around 25%. The conversion efficiency of the current photovoltaic technology is not enough to support the real solar powered electric car. In addition, the in-negligible self-weight of the current photovoltaic system prohibits the practical solar powered electric car based on the current frame work of electric vehicle.

Taking into account of the collecting area of solar radiation, conversion efficiency, self-weight, and cost, to realize the practical solar powered electric vehicle, a revolutionary frame work of the solar powered electric vehicle and a design paradigm of the photovoltaic system for the solar powered electric vehicle must be created.

The current approach of solar powered electric vehicle is to cover as much as possible surface area of the conventional electric vehicle with thin film solar cells or bulk material solar cells to generate power. Under the standard solar radiation, the typical silicon solar cells with the typical 20% conversion efficiency on a typical 6 m² surface area of an electric vehicle can only produce 1.2 kW power, but a typical electric vehicle needs at least 20 kW power to drive. In the current approach, the flat plate panels are fabricated into the body of conventional electric vehicle, due to the large area, if the III-V group solar cells with high efficiency are adopted, the cost of the electric vehicle will be prohibitively high.

In order to extend the collection area to provide enough power for driving the electric vehicle, the present invention introduces a foldable inflatable solar trailer with high conversion concentrating photovoltaic system to power the electric vehicle. The trailer is constructed with multiple inflatable non-imaging solar concentrator based high efficiency concentrating photovoltaic systems. The trailer is consist of multiple sections which can be folded into one section, and each section is an inflatable non-imaging concentrator based concentrating photovoltaic system with ultra-high efficiency, extremely low cost and super-light self weight.

### SUMMARY

According to the present invention, a solar powered electric vehicle comprising a conventional electric vehicle and a foldable inflatable non-imaging solar concentrator based concentrating photovoltaic system trailer is provided to extend the surface area to collect solar radiation, and reduce the self-weight, raise the efficiency, reduce the cost of the photovoltaic systems. Comprehended by the invention is a trailer with multiple units, which are hanged together one by one and are foldable into one entity, and each of which is equipped with an inflatable non-imaging concentrator based concentrating photovoltaic system. When in operation, the trailer is opened and the inflatable non-imagine concentrator is inflated to collect sunlight to generate power which is transferred to the front electric vehicle. When it is closed, the inflatable non-imaging concentrators are collapsed by releasing the air and the units are folded into one entity.

The inflatable non-imaging concentrator of the present invention realizes the large scale sunlight condensation with extremely low cost and super-light weight and is foldable after releasing the air or other type gases. Each of the inflatable non-imaging concentrator, which can concentrate both beam light and diffuse light, forms a concentrating photovoltaic unit which is mounted on a trailer component, which then be folded up into one entity. The electric vehicle with such a trailer will release the folded trailer on the road outside of the urban area and fold up the trailer in the urban area. When the electric vehicle parks in a spot of parking lot, the folded trailer is attached to the back of the vehicle.

Further aspects and advantages of the present invention will become apparent upon consideration of the following description thereof, reference being made of the following drawing.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is the schematic structure of the electric vehicle with a foldable inflatable solar concentrator based concentrating photovoltaic system trailer.

FIG. 2 is the structure of the foldable inflatable solar concentrator based concentrating photovoltaic system trailer.

FIG. 3 is the inflatable non-imaging solar concentrator.

FIG. 4 is the inflatable non-imaging solar concentrator based concentrating photovoltaic system unit.

FIG. 5 is the work principle of the non-imaging solar concentrator which works for both beam light and diffuse light.

FIG. 6 is the foldable trailer chain.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

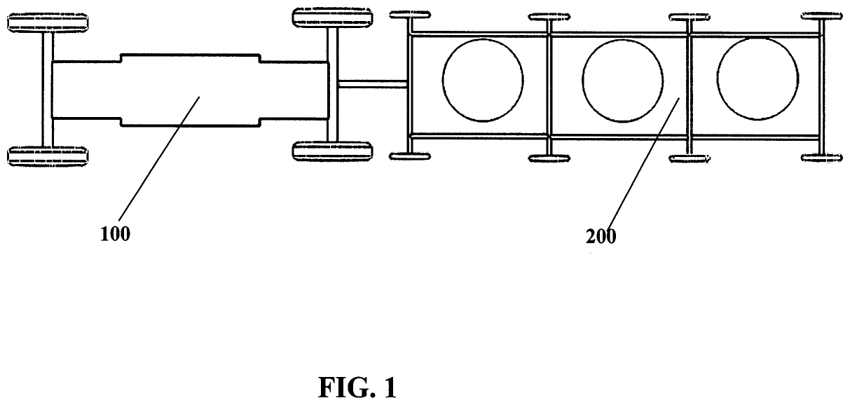

Referring to FIG. 1, the electric vehicle is consist of a conventional electric vehicle 100 which can be charged when it is moving, and a foldable inflatable solar concentrator based concentrating photovoltaic system trailer 200 which can charge the electric vehicle when it is moving.

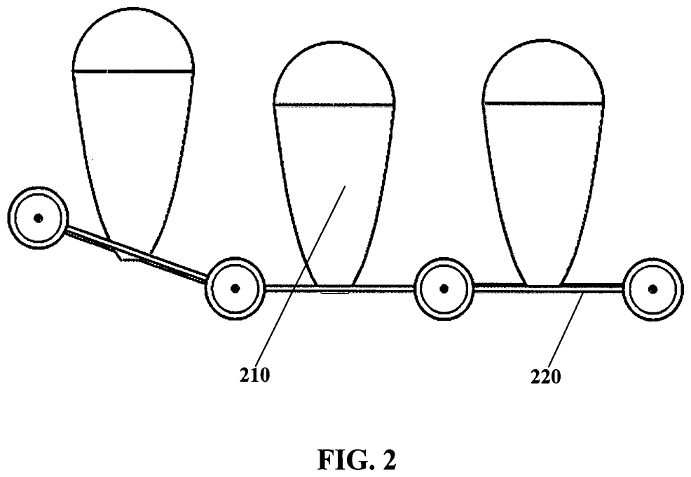

Referring to FIG. 2, the foldable inflatable solar concentrator based concentrating photovoltaic system trailer is consist of a trailer chain with multiple concentrating photovoltaic units based on the inflatable non-imaging concentrator 210 and the trailer unit frame 220.

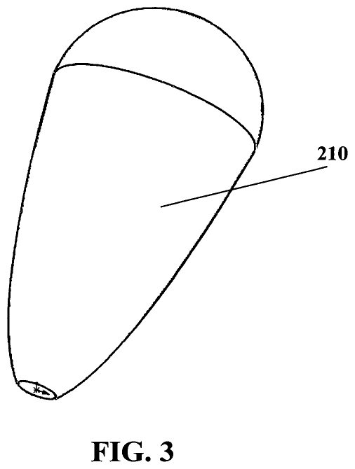

Referring to FIG. 3, the inflatable non-imaging concentrator 210 is a balloon type concentrator made of light thin film materials, which can stand up and against wind load without support materials, and which can be collapsed by leasing air. The volume and the cross section area of the concentrator can be extended largely without cost of too much of the materials.

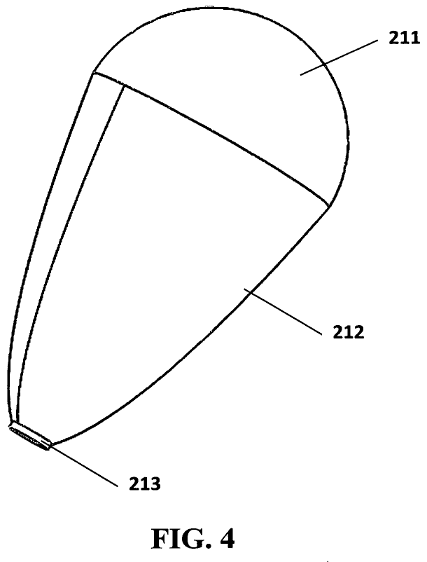

Referring to FIG. 4, the inflatable non-imaging concentrator based concentrating photovoltaic unit is made of the transparent film 211, the reflective film 212, and the photovoltaic receiver 213.

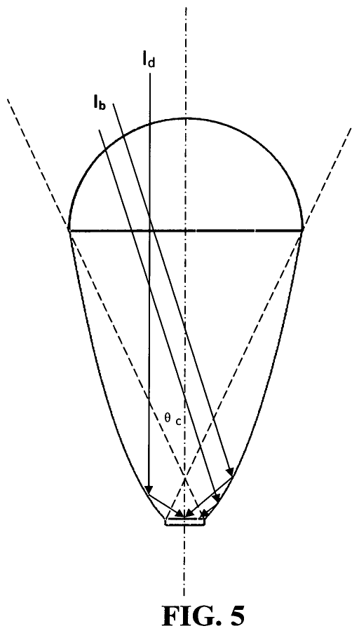

Referring to FIG. 5, the inflatable non-imaging concentrator can concentrate both beam light I_{b} and diffuse light I_{d}, as long as the incident light fall in the half-acceptance angle θ_{C}.

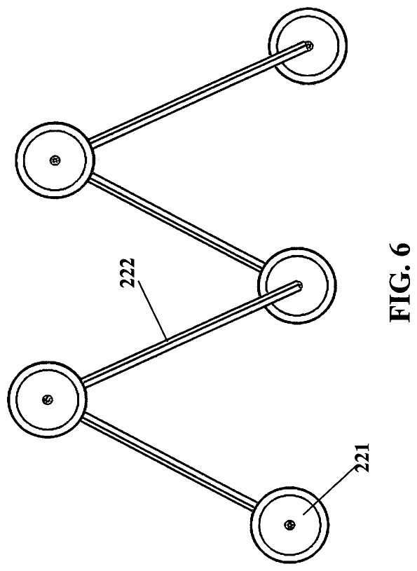

Referring to FIG. 6, the trailer chain with the multiple trailer units made of the wheels 221, and the frames 222, can be folded up.

The work principle of the electric vehicle is elucidated as the following: when in operation, the trailer is unfolded and the inflatable concentrators are inflated up, then the concentrating photovoltaic systems start to generate electric power to charge the electric vehicle in the front. When the electric vehicle is driving on the road, the trailer is generating the power and continuously charging the electric vehicle.

From the description above, a number of advantages of the electric vehicle become evident. The solar collection area of the electric vehicle is dramatically extended by the trailer and able to generate enough power to drive the electric vehicle. The trailer mounted with the inflatable non-imaging solar concentrator based concentrating photovoltaic system is light. The inflatable non-imaging concentrators concentrate not only the beam light but also diffuse light, so the electric vehicle is useable in both cloudy areas and sunny areas. The inflatable non-imaging solar concentrators reduce the areas of photovoltaic receivers and significantly reduce the cost of photovoltaic systems. Finally, the trailer is foldable, it can be folded up in urban areas and in parking lots.

In the preceding specification, various preferred embodiments have been described with reference to the accompanying drawings. It will, however, be evident that various other modifications and changes may be made thereto, and additional embodiments may be implemented, without departing from the broader scope of the invention as set forth in the claims that follow. The specification and drawings are accordingly to be regarded in an illustrative rather than restrictive sense.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

I claim:

1. A solar powered electric vehicle, comprising a conventional electric vehicle and a concentrating photovoltaic trailer,
Wherein, the concentrating photovoltaic trailer drives the electric vehicle and charges the battery bank in the said conventional electric vehicle.

2. The electric vehicle of claim 1, is chargeable when it is driving on road.

3. The concentrating photovoltaic trailer of claim 1, is consist of inflatable non-imaging solar concentrator based concentrating photovoltaic systems mounted on multiple trailer units connected with hinges.

4. The concentrating photovoltaic trailer of claim 3, is formed by hinging multiple trailer units to form a foldable chain.

5. The inflatable non-imaging solar concentrator of claim 3, is inflated into a 3 dimensional Compound Parabolic Concentrator (CPC) at the bottom of the concentrator.
